(19) United States
(12) Patent Application Publication
(10) Pub. No.: US 2003/0063022 A1
(43) Pub. Date: Apr. 3, 2003

(54) Method and apparatus for digital-to-analog conversion with improved signal-to-noise and distortion ratio

(76) Inventors: Patrik Eriksson, Kolmarden (SE); Peter Magnus Petersson, Jarfalla (SE)

Correspondence Address: NIXON & VANDERHYE P.C., 8th Floor, 1100 North Glebe Road, Arlington, VA, 22201, US

(21) Appl. No.: 09/964,888

(22) Filed: Sep. 28, 2001

(51) Int. Cl. H03M 1/66

(52) U.S. Cl. 341/144

(57) ABSTRACT

A digital-to-analog signal conversion method and apparatus provide increased dynamic range. An input signal is mapped to plural digital-to-analog converters. Outputs from two or more of the digital-to-analog converters are combined to generate an output signal having a greater signal-to-noise-and-distortion ratio than would be achieved with a single digital-to-analog converter. In a preferred example embodiment, the output signals are combined without including a quantization noise associated with each of the digital-to-analog converters. Indeed, the combined signal includes the quantization noise associated with only one of the digital-to-analog converters.

### FIELD OF THE INVENTION

The present invention relates generally to digital-to-analog conversion, and more particularly, to digital-to-analog conversion which provides a large dynamic range and high signal-to-noise ratio.

### BACKGROUND AND SUMMARY OF THE INVENTION

In many applications, it is necessary to convert a digital signal to an analog equivalent where the analog signal is typically a voltage or current corresponding to the value of a digital word. The dynamic range of a digital-to-analog converter is determined by the size (number of bits) of the digital code range handled by the digital-to-analog converter. Dynamic range is often defined as the difference in decibels between the noise level and the level at which the output is saturated, i.e., the overload level. The cost of digital-to-analog converters increases as the code range increases to larger bit widths.

One example application of digital-to-analog converters is in multicarrier transmitters. A typical multicarrier data stream includes, for example, N independent baseband data streams, each representing a separate frequency channel. Each baseband data stream modulates its corresponding digital carrier signal. The N-modulated carriers are summed in the digital domain before being applied to a digital-to-analog converter which converts that multicarrier signal into the analog domain. The composite analog signal is frequency-up converted (one or several times), amplified, and filtered before being transmitted via an antenna.

A simplified block diagram of a multicarrier transmitter is shown in FIG. 1. N data streams 12A-12N are separately processed in corresponding signal processing blocks 14A-14N in which those processing operations are performed for example symbol mapping, pulse shaping, and power control. The processed baseband data streams are then quadrature modulated onto various frequency carriers f₁-f_{N} using corresponding oscillators 18A-18N and mixers 16A-16N. The quadrature modulated information is summed at summer 20 into a single digital input stream converted in the digital-to-analog converter 22. The analog signal is frequency converted, filtered, and amplified, as indicated at block 24, before being transmitted over antenna 26.

The resulting composite signal generated by the digital summer 20 will generally have a high Peak-to-Average power ratio (PAR). The peak signal power of the multicarrier signal with M carriers can be defined as:

$${P}_{p e a k} = {M}^{2} {V}_{p e a k}^{2} \qquad ( 1 )$$

assuming M carries all with a peak voltage of Vₚₑₐₖ and a reference resistance of 1 ohm. If the individual baseband signals are of constant envelope, the average signal power in the composite multicarrier signal is as follows:

$${P}_{a v e r a g e} = \frac{M {V}_{p e a k}^{2}}{2} \qquad ( 2 )$$

The peak-to-average ratio (PAR) reduces to

PAR=2M (3)

The expression used here for PAR refers to signal average power and not to envelope average power. The signal average power is 3 dB lower than the envelope average power due to the carrier frequency up conversion.

The scale of a digital-to-analog converter includes a range of digital codes from a zero analog level output code to a full scale (FS) or maximum analog level output code. Since the peak-to-average power ratio (PAR) increases with the number of carriers, it is necessary to increase the amount of “back-off” from the full scale value in the digital-to-analog converter to ensure that the multicarrier signal is not clipped by the digital-to-analog converter or does not saturate the amplification stage 24. Clipping of the signal causes distortion both in-band and out-of-band during the time when the clipping event occurs. However, if the clipping event has a low probability, i.e., occurs only for a low fraction of the time, the clipping does not produce a very high average distortion power.

For a larger number of carriers, the central limit theorem is applicable, and the distribution of the instantaneous signal voltage of the multicarrier signal may be considered Gaussian regardless of the voltage distribution of the individual carriers. In this situation, it is not necessary to employ a “back-off” from the digital-to-analog converter full scale for a worst possible case, i.e., in-phase addition of all carrier peaks. Instead, the transmitter may be dimensioned from a Complementary, Cumulative Distribution Function (CCDF) of the actual signal, (which approximates a Gaussian distribution), and the acceptable level of intermodulation in the system.

Even taking advantage of the statistical nature of a multicarrier signal and using a state-of-the-art digital-to-analog converter, the required back-off from the digital-to-analog converter full scale is such that the signal-to-noise ratio (SNR) and/or signal-to-distortion ratio (SDR) of the digital-to-analog converter may be too low to meet system requirements. Accordingly, there is a need to increase the dynamic range over which the digital-to-analog converter can produce a suitable output signal (without clipping, saturation, or other distortion) in response to an input signal than what is achievable with a single, state-of-the-art, digital-to-analog converter. The present invention meets this need.

A digital-to-analog signal conversion method and apparatus provide increased dynamic range. An input signal is mapped to plural digital-to-analog converters. Outputs from two or more of the digital-to-analog converters are combined to generate an output signal having a greater signal-to-noise-and-distortion ratio than would be achieved with a single digital-to-analog converter. In a preferred example embodiment, the output signals are combined without including a quantization noise associated with each of the digital-to-analog converters. Indeed, the combined signal includes the quantization noise associated with only one of the digital-to-analog converters. In another example embodiment, the quantization noise of a first of the digital-to-analog converters is decorrelated from the quantization noise of a second of the digital-to-analog converters before combining. A further example embodiment, as applied to a multicarrier input signal, divides certain carriers of the multicarrier signal into multiple frequency subbands. Each of the subbands is mapped to a corresponding one of the digital-to-analog converters, and the outputs of the digital-to-analog converters are combined. In all of these example embodiments, a larger dynamic range is achieved in the combined signal from the plural digital-to-analog converters than would be achieved with only a single digital-to-analog converter.

In a preferred one of the example embodiments, the digital code range to be covered by the digital-to-analog conversion is divided into plural digital code regions. Each code region is assigned to one of plural digital-to-analog converters. A vale of a digital signal sample to be converted into analog form is determined. Based on that value, the sample is mapped to appropriate ones of the digital-to-analog converters. One of the digital-to-analog converters generates an output corresponding to the digital signal sample that is less than its full scale value. Another one of the digital-to-analog converters generates a second output that is full scale. The first and second outputs are combined to generate the analog output signal. An additional output may be generated from a third converter at its respective full scale signal level depending upon the sample's value. A combining circuit combines the first, second, third, (and any other additional outputs) to provide the analog signal. The combined signal includes the quantization noise associated only with the first digital-to-analog converter. The second, third, or any other additional analog converters do not contribute substantial quantization noise.

### BRIEF DESCRIPTION OF THE DRAWINGS

The foregoing and other objects, features, and advantages of the invention will be apparent from the following description of preferred, non-limiting example embodiments, as well as illustrated in the accompanying drawings. The drawings are not to scale, emphasis instead being placed upon illustrating the principles of the invention.

FIG. 1 is a function block diagram of a multicarrier transmitter;

FIG. 2 is a graph illustrating quantization;

FIG. 3 is a block diagram illustrating a simplified transmitter incorporating a digital-to-analog conversion apparatus in accordance with one example, non-limiting embodiment of the present invention;

FIG. 4 is a graph illustrating an input sample waveform;

FIG. 5 is a flowchart diagram illustrating a digital-to-analog conversion procedure in accordance with the example embodiment shown in FIG. 3;

FIGS. 6 and 7 are function block diagrams illustrating simplified transmitters that incorporate analog-to-digital conversion apparatus in accordance with other example embodiments of the present invention; and

FIG. 8 is a general digital-to-analog conversion procedure in accordance with the present invention encompassing the three specific example, non-limiting embodiments disclosed.

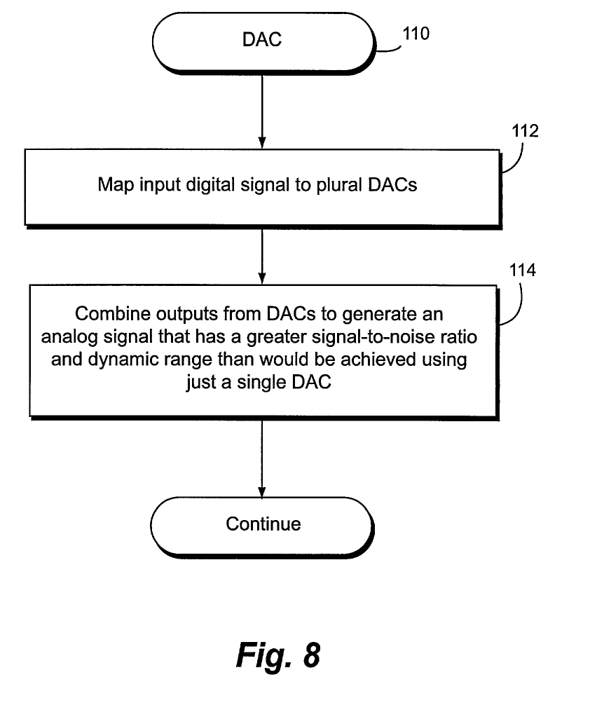

### DETAILED DESCRIPTION

In the following description, for purposes of explanation and not limitation, specific details are set forth, such as particular embodiments, procedures, techniques, etc., in order to provide a thorough understanding of the present invention. However, it will be apparent to one skilled in the art that the present invention maybe practiced in other embodiments that depart from these specific details. In some instances, detailed descriptions of well-known methods, interfaces, devices and processing techniques are omitted so as not to obscure the description of the present invention with unnecessary detail. Moreover, individual function blocks are shown in some of the figures. Those skilled in the art will appreciate that the functions may be implemented using individual hardware circuitry, using software functioning in conjunction with a suitably programmed digital microprocessor or general purpose computer, using an Application Specific Integrated Circuit (ASIC), and/or using one or more Digital Signal Processors (DSPs).

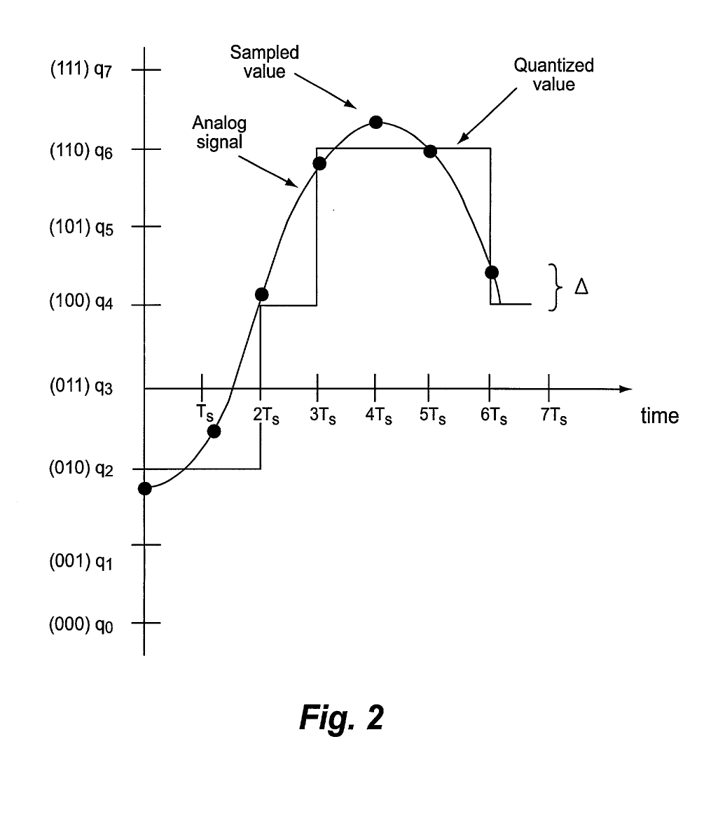

By way of additional background relating to quantization noise, each sample of an analog signal may be represented by one of a number of finite signal levels. The number of signal levels is determined by the number of bits used to represent every sample. For the illustration in FIG. 2, three bits are used. There are 2³=8 signal levels: qₒ-q₇. FIG. 2 shows the principle of uniform quantization with each analog sample being assigned a corresponding one of the eight digital codes. With a finite number of levels, a continuous analog signal cannot be exactly represented. Typically, there is a difference, labeled Δ in FIG. 2, between the sampled value and the quantized value. This Δ is the quantization error. The size of Δ can be decreased by increasing the number of discrete levels, which increases the number of bits needed to represent each of the different corresponding digital codes.

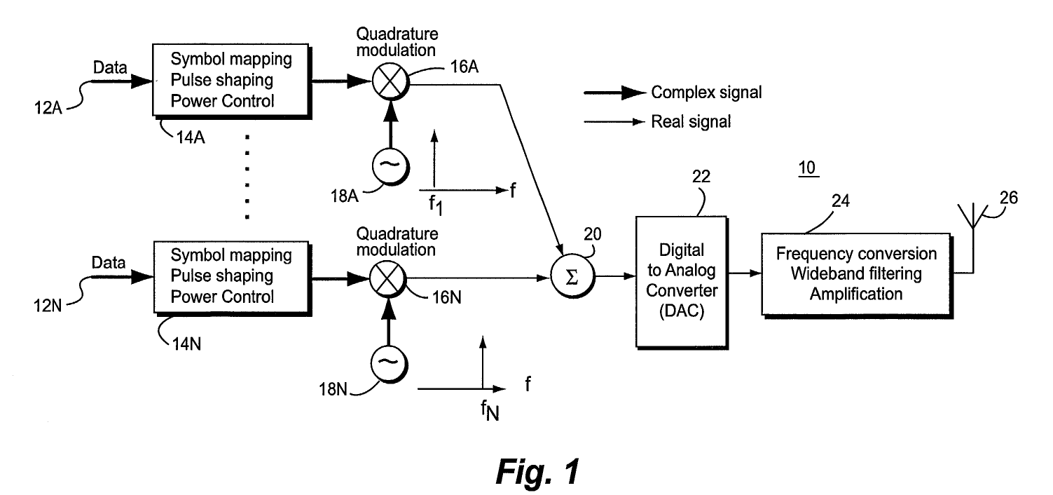

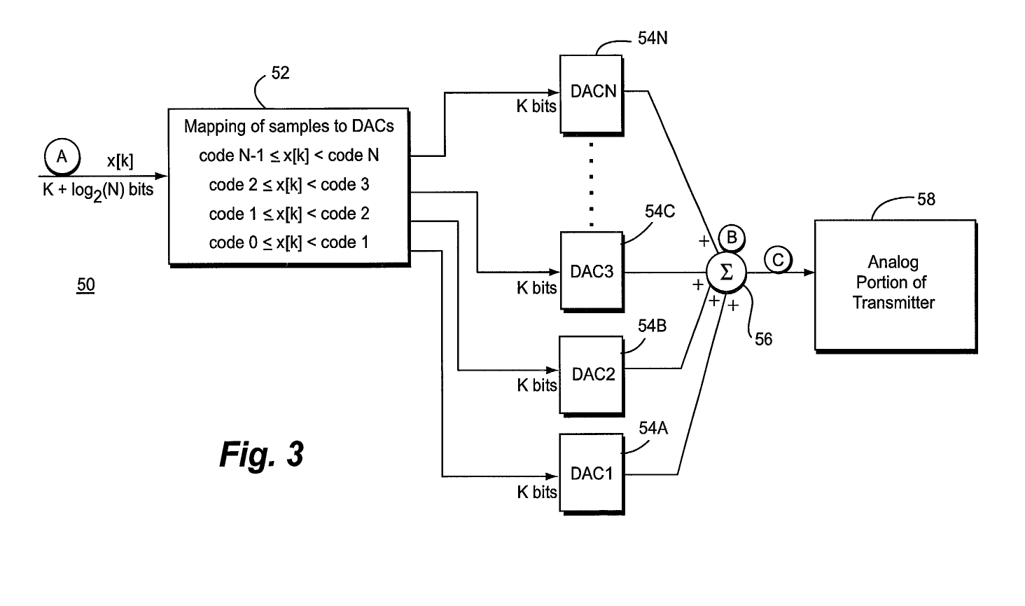

FIG. 3 shows a preferred, non-limiting example embodiment of the present invention in a transmitter 50. Such a transmitter may be used in one example application as a multicarrier transmitter such as that shown in FIG. 1. A digital signal is input at point A to a mapper 52. One example of the digital input signal is a multicarrier digital signal as described above. The digital signal is mapped to a plurality of digital-to-analog converters (DAC1-DACN) 54A-54N based upon the value of the digital input signal determined by the mapper 52. Each of the N digital-to-analog converters 54 is assigned a portion of the total digital code range assigned for digital-to-analog conversion. Thus, the total code range is divided into N, non-overlapping regions with the union of all N regions equal to the whole code set. The outputs of the digital-to-analog converters are summed at point B to generate a corresponding analog signal shown at point C which is provided to an analog portion 58 of the transmitter for subsequent transmission.

A disadvantage with adding signals from plural digital-to-analog converters, with respect to achieving a higher signal-to-noise ratio or signal-to-distortion ratio sometimes jointly referred to as signal-to-noise-and-distortion ratio (SINAD), is that each digital-to-analog converter contributes a substantial quantization noise to the combined output signal. However, this disadvantage is avoided in the preferred example embodiment shown in FIG. 3.

After determining the value of a digital input sample x[k] at point A, if the value of the digital sample x[k] is between the signal level corresponding to code 0 and code 1, the sample x[k] is only mapped to DAC1 54A, and only DAC1 generates an output signal. However, if the digital sample x[k] is greater than the signal level corresponding to code 1, but less than the signal level corresponding to code 2, the DAC2 generates a signal having a signal level corresponding to the input digital code to the summer 56. In addition, the full scale signal level output of DAC1 is sent to the summer 56. Similarly, if the digital sample is greater than the signal level corresponding to code 2 but less than the signal level corresponding to code 3, the DAC3 generates a corresponding signal level associated with the digital code while DAC2 and DAC1 generate their full scale analog signals. All three output signals from DAC1, DAC2, and DAC3 are summed at summer 56.

In any event, only one digital-to-analog converter at a time delivers a varying output signal over time, i.e., the output signal varies between the digital-to-analog converter's zero and FS to summation point B. The other digital-to-analog converter(s) provide(s) a full scale “static” signal. As a result, the total quantization noise in the output signal from the summer is equal to only one of the digital-to-analog converters. Summing the full scale signal level of a digital-to-analog converter does not contribute substantial quantization noise, and hence, does not increase the overall noise floor. It is to be understood that these “static” digital-to-analog converters generating this full scale output contribute some small noise, both thermal noise and perhaps some small DC quantization noise, but this normally does not amount to a significant noise source. Accordingly, this is the meaning to be understood when reference is made to a full scale analog-to-digital converter not contributing quantization noise to the combined signal.

Assuming the use of N digital-to-analog converters, the signal power achievable in the digital-to-analog conversion is increased by 20logN dB compared to a single digital-to-analog converter. Therefore, the signal-to-noise-and-distortion ratio of the combined analog signal at point C in FIG. 3 is also increased by 20logN dB compared to a single digital-to-analog converter. This is a significant increase over the signal-to-noise-and-distortion ratio achievable when using only a single analog-to-digital converter

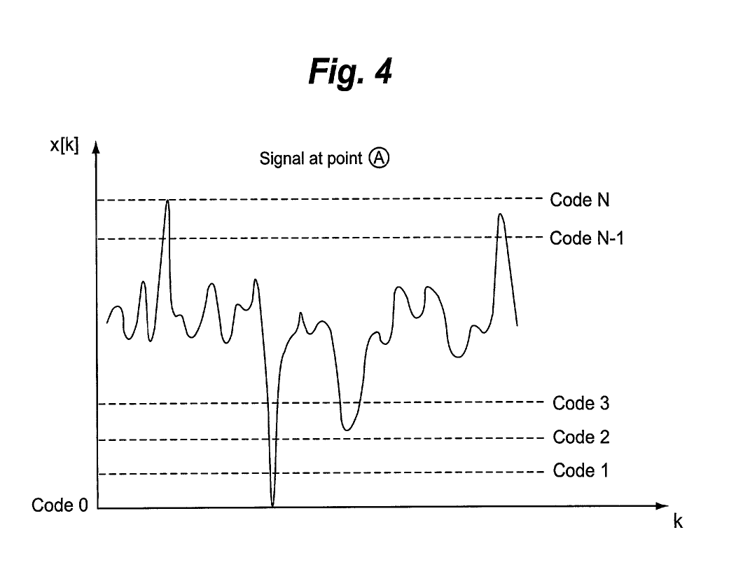

FIG. 4 illustrates a graph of the sampled digital input x[k] relative to sample number k. The signal levels corresponding to code 1 to code N are indicated with dashed lines. The signal sample at any one time falls between two of the codes. Only the digital-to-analog converter assigned to this code range contributes its quantization noise. The outputs of digital-to-analog converters at lower code ranges do not contribute substantial quantization noise because they are outputting at their full scale value. Digital-to-analog converters at higher code ranges do not generate an output.

Consider the following simple example. Assume each individual digital-to-analog converter has a resolution of two bits and that a straight binary number representation is used. As a result, the input digital code range for each digital-to-analog converter is four bits {0, 1, 2, 3}. Assume also there are four digital-to-analog converters. The following notation is applicable:

Code 0=0

Code 1=4

Code 2=8

Code 3=12

Code 4=16

The maximum output or voltage of each digital-to-analog converter is its full scale signal level. The quantization error in each digital-to-analog converter is determined by its resolution and its full scale, i.e., how much analog signal level (current or voltage) is represented by the least significant bit in each digital-to-analog converter.

The digital input is represented by four bits corresponding to a decimal value between 0 and 15. Assume an input signal corresponding to a decimal value of 10 is provided at sample time k, i.e., x[k]=10. Since code 2 (8)<x[k]<code 3 (12), DAC1 and DAC2 each provide an analog signal (a voltage or a current) corresponding to its full scale value to the summation point. On the other hand, DAC3 provides an analog output value corresponding to 10−8=2, which is less than its full scale value. Assume at the next sample interval that x[k+1]=9, DAC1 and DAC2 still provide an analog output corresponding to their respective full scales. However, DAC3 now provides an analog output value corresponding to 10−9=1. In both sample times, k and k+1, only DAC3 contributes to the quantization error. The resolution provided by these four digital-to-analog converters, even though each DAC only has a resolution of two bits, is four bits. The SINAD increase of this example compared to a single DAC is 20log4 which equals 12 dB.

Accordingly, the present invention as implemented in the preferred non-limiting example embodiment above, provides a higher SINAD and dynamic range than what is otherwise achievable using only a single digital-to-analog converter. When used in applications concerned with peak-to-average power ratio (PAR), where signal peaks do not occur very frequently, the highest code range is allocated to these infrequent signal peaks. Due to the infrequent occurrence of these peaks, the highest code range digital-to-analog converter may, if desired, have a lower performance and lower dynamic range than the other digital-to-analog converters without adversely impacting performance.

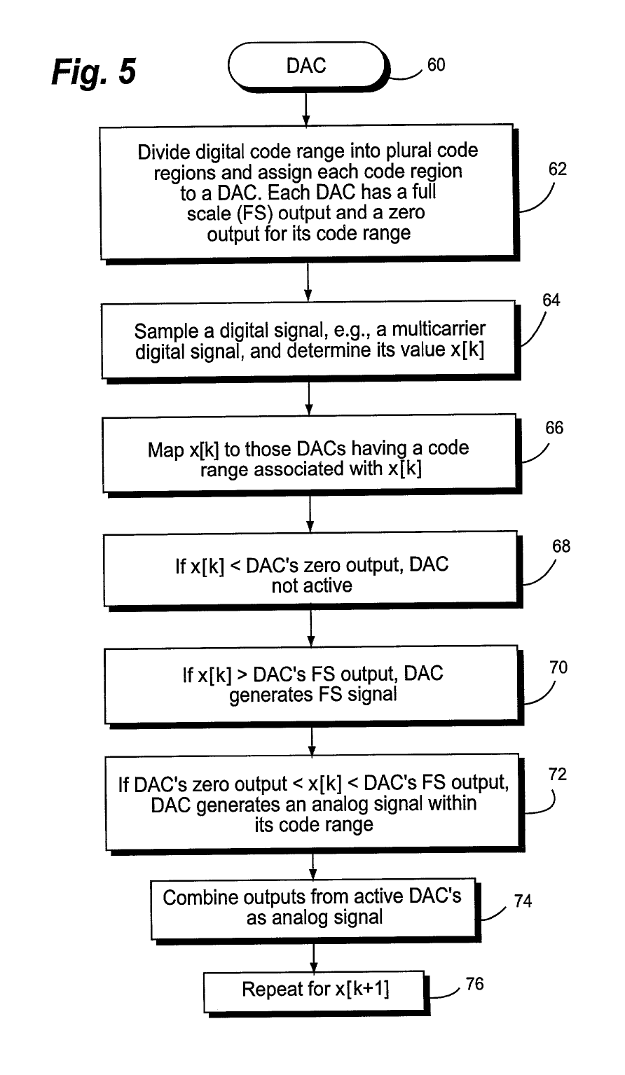

FIG. 5 illustrates a digital-to-analog conversion routine (block 60) in accordance with a preferred, non-limiting, example embodiment shown in FIGS. 3 and 4. The digital code range covered by the digital-to-analog conversion is divided into plural code regions, and each digital-to-analog converter is assigned to one of the divided code regions. Each digital-to-analog converter has a full-scale (FS) output and a zero output for its allocated code range (block 62). A digital signal, (e.g., a multicarrier digital signal), is sampled, and its value is determined (block 64). The signal sample is mapped to those digital-to-analog converters having code range associated with the value of the digital sample (block 66). Specifically, if the value of the signal sample is less than a digital-to-analog converter's zero code output, the digital-to-analog converter is not active in this sample's conversion and does not provide an output signal to the summer (block 68). If the value of the sample is greater than the digital-to-analog converter's full scale code output, this digital-to-analog converter simply outputs its full scale signal (block 70). On the other hand, if the sample value is greater than a digital-to-analog converter's zero code level, but less than the digital-to-analog converter's FS code level, the digital-to-analog converter generates an analog signal corresponding to the sample value within its code range (block 72). The output signals from all active digital-to-analog converters are combined to generate a composite analog signal (block 74). This process is repeated for the next signal sample (block 76).

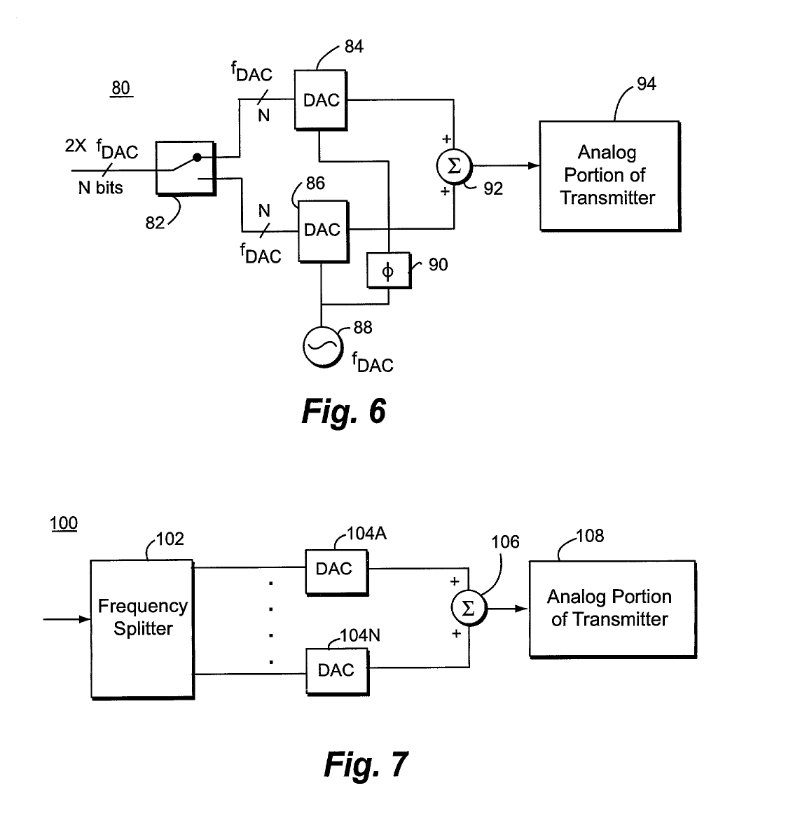

The present invention is not limited to the preferred, non-limiting, example embodiment described above. For example, FIG. 6 illustrates a simplified transmitter 80 o with a digital-to-analog conversion apparatus employing plural digital-to-analog converters in accordance with another example embodiment of the present invention. In this example embodiment, the multicarrier input signal is represented by samples taken at a rate of two times the digital-to-analog converter update rate f_{DAC} the frequency of the digital-to-analog converter update clock. f_{DAC} updates the analog output value from the digital-to-analog converter once every clock cycle. The data stream is demultiplexed or split in a demultiplexer 82 into two digital-to-analog converter branches. The two in-phase multicarrier signals are converted to analog signals in respective digital-to-analog converters 84 and 86. An oscillator or other clock source 88 provides f_{DAC} to one digital-to-analog converter 86 and the same signal f_{DAC} but 180° out of phase via block 90 to the other digital-to-analog converter 84. It is to be understood that FIG. 6 is conceptual, and in practice, the demultiplexing would likely occur at an earlier signal processing stage.

The outputs from the digital-to-analog converters 84 and 86 are summed in summer 92, and the output analog signal is provided to the analog portion 94 of the transmitter. The quantization noise associated with each digital-to-analog converter output is decorrelated by the scheme illustrated in FIG. 6. More specifically, if the output signals from each digital-to-analog converter are random in nature at each point in time, they are uncorrelated. Because the outputs from the digital-to-analog converters are uncorrelated, each digital-to-analog converter's quantization error is also uncorrelated. The same effect may also be achieved by using identical samples in both digital-to-analog converters, and instead decorrelating the quantization noise of the two analog converters with out-of-band digital dither (digital noise). This approach ensures that the intermodulation products and harmonics generated in the two digital-to-analog converters do not add in-phase at summer 92 even if the transfer functions of the digital-to-analog converters 84 and 86 are identical. Because the output signals of the digital-to-analog converters add in-phase, but the noise/dither and distortion do not, the signal-to-noise and distortion ratio is increased by 3 dB. This scheme can be extended by using N digital-to-analog converters which would give an improvement in SINAD of 10logN dB. This scheme is not as desirable as to the preferred approach which provides an improvement of 20log N dB using N digital-to-analog converters.

Another example embodiment is illustrated in the function block diagram of a simplified transmitter 100 in FIG. 7. The input digital signal is provided to a frequency splitter 102 which splits the multicarrier signal consisting of M carriers into a number of subbands. Those different subbands (containing one or several carriers) are directed to different digital-to-analog converters 104A-104N. As a result, the required back-off in each digital-to-analog converter can be reduced. The peak-to-average power ratio (PAR) is 2M for M carriers. Decreasing M reduces the PAR, and therefore, a smaller back-off or margin needed to ensure the signal is not clipped in the digital-to-analog converter may be used. Assuming N digital-to-analog converters and M/N carriers in each subband, the potential increase in individual carrier power is 20log N. However, the increase in quantization noise and distortion power at the summation point 106, where the multicarrier analog signal is generated and provided to the analog portion 108 of the transmitter, is 10logN. As a result, the effective increase in SINAD using this approach is limited to 10logN. Explicit decorrelation of the quantization noise from different digital-to-analog converters is not required in this approach because the subband signals are not strongly correlated. Because the signals are at different carrier frequencies and are each modulated with independent data, they are uncorrelated. The amplitude distribution of the multicarrier signal is typically such that for many carriers, it is not necessary to back-off for the worst case peak value since the probability of the worst case actually occurring is low. However, for a smaller number of carriers, the probability is higher and full back-off is required. The benefit of this approach is reduced in this latter situation.

While the present invention has been described with respect to particular example embodiments, those skilled in the art will recognize that the present invention is not limited to those specific embodiments described and illustrated herein. Different formats, embodiments, adaptations besides those shown and described, as well as many modifications, variations and equivalent arrangements may also be used to implement the invention. Although the present invention is described in relation to preferred example embodiments, it is to be understood that this disclosure is only illustrative and exemplary of the present invention. The scope of the invention is defined by the appended claims.

What is claimed:

1. A digital-to-analog signal conversion method, comprising:
mapping an input signal to plural digital-to-analog converters, and
combining output signals from at least two of the digital-to-analog converters to generate an output signal that has a greater signal-to-noise ratio than would be achieved with a single digital-to-analog converter.

2. The method in claim 1, wherein the output signals are combined without including a quantization noise associated with each of the digital-to-analog converters.

3. The method in claim 2, wherein the output signal includes the quantization noise associated with only one of the digital-to-analog converters.

4. The method in claim 1, further comprising:
decorrelating a quantization noise of a first of the two digital-to-analog converters from a quantization noise of a second of the two digital-to-analog converters before the combining.

5. The method claim 1, wherein the input signal is a multicarrier signal, the method further comprising:
dividing certain carriers of the multicarrier signal into multiple frequency subbands, and
mapping each of the subbands to a corresponding one of the digital-to-analog converters.

6. A digital-to-analog signal conversion method, comprising:
mapping an input signal to plural digital-to-analog converters, and
combining signals from plural digital-to-analog converters to generate an output signal so that a larger dynamic range is achieved in the digital-to-analog signal conversion than would be achieved with only a single digital-to-analog converter.

7. The method in claim 6, wherein the signals from the plural digital-to-analog converters are combined without including a quantization noise associated with each of the digital-to-analog converters.

8. The method in claim 7, wherein the combined signals include the quantization noise associated with only one of the digital-to-analog converters.

9. The method in claim 8, further comprising:
dividing a digital code range corresponding to the digital-to-analog conversion into plural digital code regions, each of the plural digital-to-analog converters being associated with one of the plural digital code regions, and
based on a value of a digital signal sample to be converted to analog form, generating a first output from one of the plural digital-to-analog converters at less than its full scale value and a second output from another of the plural digital-to-analog converters at its full scale value; and
wherein the combining includes combining the first output and the second output to generate the output signal.

10. The method in claim 6, further comprising:
decorrelating a quantization noise of a first of the digital-to-analog converters from a second of the digital-to-analog converters before the combining.

11. The method claim 6, wherein the input signal is a multicarrier digital signal, the method further comprising:
dividing certain carriers of the multicarrier signal into multiple frequency subbands, and mapping each of the subbands to a corresponding one of the digital-to-analog converters.

12. A method for converting a digital signal into an analog signal, comprising:
mapping the digital signal to first and second digital-to-analog converters;
generating a first output from the first digital-to-analog converter signal level related to the digital signal that is less than a full scale signal level of the first digital-to-analog converter;
generating a second output from the second digital-to-analog converter at a signal level related to the digital signal that is at a full scale signal level of the second digital-to-analog converter; and
combining the first and second outputs to provide the analog signal.

13. The method in claim 12, the method further comprising:
generating a third output from a third digital-to-analog converter at a signal level related to the sample value that is at a full scale signal level of the second digital-to-analog converter,
wherein the combining includes combing the first, second, and third outputs to provide the analog signal.

14. The method in claim 12, further comprising:
determining a value of a sample of the digital signal for an associated sampling interval,
wherein the mapping and generating steps are performed using the determined value.

15. The method in claim 12, wherein the first and second outputs are combined without including a quantization noise associated with each of the first and second digital-to-analog converters.

16. The method in claim 15, wherein the combined signals include a quantization noise associated with only the first digital-to-analog converter.

17. The method in claim 12, wherein the signal combining provides an increased signal-to-noise ratio for the digital-to-analog signal conversion as compared to digital-to-analog conversion by a single digital-to-analog converter.

18. The method in claim 12, wherein the signal combining provides an increased dynamic range for the digital-to-analog signal conversion as compared to digital-to-analog conversion by a single digital-to-analog converter.

19. A digital-to-analog signal conversion apparatus, comprising:
first and second digital-to-analog converters, and
a combiner configured to combine a first output from the first digital-to-analog converter and a second output from the second digital-to-analog converter to generate an output signal that has a greater signal-to-noise ratio than would be achieved with a single digital-to-analog converter.

20. The apparatus in claim 19, wherein the combiner is configured to combine the first and second outputs without including a quantization noise associated with each of the first and second digital-to-analog converters.

21. The apparatus in claim 20, wherein the combined outputs include the quantization noise associated with only one of the first and second digital-to-analog converters.

22. The apparatus in claim 19, further comprising circuitry configured to decorrelate a quantization noise of the first digital-to-analog converter from a quantization noise of the second digital-to-analog converter before the combining.

23. The apparatus in claim 19, wherein the input signal is a multicarrier signal, the apparatus further comprising circuitry configured to divide certain carriers of the multicarrier signal into multiple frequency subbands, and to map each of the subbands to a corresponding one of the digital-to-analog converters.

24. The apparatus in claim 19, wherein the combiner is configured to provide an increased signal-to-noise ratio or signal-to-distortion ratio for the digital-to-analog signal conversion apparatus as compared to digital-to-analog conversion by a single digital-to-analog converter.

25. The apparatus in claim 19, wherein the combiner is configured to provide an increased dynamic range for the digital-to-analog signal conversion apparatus as compared to digital-to-analog conversion by a single digital-to-analog converter.

26. The apparatus in claim 19, wherein the increased dynamic range is achieved without increasing distortion associated with the digital-to-analog signal conversion.

27. An apparatus for converting a digital signal to an analog signal, comprising:
first and second digital-to-analog converters each having a corresponding full scale analog output,
circuitry configured to map the digital signal to the first and second digital-to-analog converters,
where in response to the mapping, the first digital-to-analog converter is configured to generate a first output from the first digital-to-analog converter that is less than its full scale value and the second digital-to-analog converter is configured to generate a second output at its full scale, and
a combiner configured to combine the first and second outputs to provide the analog signal.

28. The apparatus in claim 27, wherein the circuitry is configured to determine a corresponding value of the digital signal and to map the digital signal using the determined value.

29. The apparatus in claim 28, further comprising:
a third digital-to-analog converter is configured to generate a third output at its full scale based on the determined value, and wherein the combiner is configured to combine the first, second, and third outputs to provide the analog signal.

30. The apparatus in claim 27, wherein the first and second outputs do not include a quantization noise from each of the first and second digital-to-analog converters.

31. The apparatus in claim 30, wherein the combined outputs include the quantization noise associated with only the first digital-to-analog converter.

32. The apparatus in claim 27, wherein a digital code range is divided into plural digital code regions with each digital-to-analog converter being associated with one of the digital code regions.

33. The apparatus in claim 27, wherein the digital signal is a multicarrier signal.
